(19) United States
(12) Patent Application Publication
(10) Pub. No.: US 2021/0328115 A1
(43) Pub. Date: Oct. 21, 2021

(54) LIGHT-EMITTING DEVICE AND METHOD FOR PRODUCING LIGHT-EMITTING DEVICE

(71) Applicant: Sony Semiconductor Solutions Corporation, Kanagawa (JP)

(72) Inventors: Hidekazu AOYAGI, Kumamoto (JP); Takahiro ARAKIDA, Kumamoto (JP); Hiroyuki OKUYAMA, Kumamoto (JP)

(21) Appl. No.: 17/272,054

(22) PCT Filed: Aug. 6, 2019
(86) PCT No.: PCT/JP2019/030814

§ 371 Date: Feb. 26, 2021

(30) Foreign Application Priority Data
Aug. 27, 2018 (JP) 2018-157968

(51) Int. Cl. H01L 33/58; H01L 33/48

(52) U.S. Cl. CPC H01L 33/58; H01L 33/483

(57) ABSTRACT

A light-emitting device according to an embodiment of the present technology includes a semiconductor light-emitting section and a base. The base supports the semiconductor light-emitting section, and includes a light extraction surface and a side surface including a concave portion and a convex portion that are alternately arranged in a specified direction. This makes it possible to control an emission direction (a scattering direction) of light emitted from the side surface. This results in being able to provide a light-emitting device that is capable of controlling light emitted from a side surface of the light-emitting device, and a method for producing the light-emitting device.

### TECHNICAL FIELD

The present technology relates to a light-emitting device such as a light-emitting diode (LED) and a method for producing the light-emitting device.

### BACKGROUND ART

Patent Literature 1 discloses an LED array for an optical printer head. The LED array disclosed in Patent Literature 1 is obtained by performing full-cut dicing at an angle from a back surface upon cutting a wafer into pieces. Consequently, the LED array includes an angled side surface such that the area of the back surface is smaller. This results in being able to perform alignment in the LED array at a high degree of accuracy and to prevent leaked light (for example, the lower right column on page 3, and FIG. 2 in Patent Literature 1).

### CITATION LIST

### Patent Literature

Patent Literature 1: Japanese Patent Application Laid-open No. 2-010879

### DISCLOSURE OF INVENTION

### Technical Problem

As described above, there is a need for a technology that enables a light-emitting device such as an LED to control light emitted from a side surface of the light-emitting device.

In view of the circumstances described above, an object of the present technology is to provide a light-emitting device that is capable of controlling light emitted from a side surface of the light-emitting device, and a method for producing the light-emitting device.

### Solution to Problem

In order to achieve the object described above, a light-emitting device according to an embodiment of the present technology includes a semiconductor light-emitting section and a base.

The base supports the semiconductor light-emitting section, and includes a light extraction surface and a side surface including a concave portion and a convex portion that are alternately arranged in a specified direction.

In this light-emitting device, a concave portion and a convex portion arranged in a specified direction are formed on a side surface of a base that includes a light extraction surface. This makes it possible to control an emission direction (a scattering direction) of light emitted from the side surface.

The side surface may include a plurality of the concave portions and a plurality of the convex portions, and the concave portion and the convex portion may be alternately arranged one by one in the specified direction.

The concave portion and the convex portion may be alternately arranged in a direction orthogonal to an exit direction of light that exits from the light extraction surface.

The concave portion and the convex portion may be alternately arranged in a direction orthogonal to a perpendicular direction of the light extraction surface.

The base may have a rectangular-parallelepiped shape. In this case, the side surface may be a surface orthogonal to the light extraction surface.

The base may have a cylindrical shape of which an axis direction is a perpendicular direction of the light extraction surface. In this case, the side surface may be a circumferential surface of the base.

The concave portion and the convex portion may be configured to extend on the side surface in a direction orthogonal to the specified direction.

the concave portions of the plurality of the concave portions may have the same shape when the plurality of the concave portions and the plurality of the convex portions are viewed from a direction orthogonal to the specified direction.

The convex portions of the plurality of the convex portions may have the same shape when the plurality of the concave portions and the plurality of the convex portions are viewed from a direction orthogonal to the specified direction.

Each of the plurality of the concave portions may have a shape of a circular arc when the plurality of the concave portions and the plurality of the convex portions are viewed from a direction orthogonal to the specified direction.

Each of the plurality of the concave portions may have a semicircular shape when the plurality of the concave portions and the plurality of the convex portions are viewed from a direction orthogonal to the specified direction.

Each of the plurality of the concave portions may have a V-shape when the plurality of the concave portions and the plurality of the convex portions are viewed from a direction orthogonal to the specified direction.

A sinusoidal shape may be formed by the plurality of the concave portions and the plurality of the convex portions when the plurality of the concave portions and the plurality of the convex portions are viewed from a direction orthogonal to the specified direction.

The concave portion and the convex portion may be alternately arranged in a direction parallel to an exit direction of light that exits from the light extraction surface.

The concave portion and the convex portion may be alternately arranged in a direction parallel a perpendicular direction of the light extraction surface.

The semiconductor light-emitting section may include at least one light-emitting source.

The at least one light-emitting source may be at least one light-emitting diode (LED).

The at least one light-emitting source may be arranged on a side of the light extraction surface of the base, or may be arranged on a side opposite to the light extraction surface of the base.

The light-emitting device may further include a cover portion that is configured to cover the light extraction surface and the side surface of the base, the cover portion including a side surface including a concave portion and a convex portion that are alternately arranged in a specified direction.

A method for producing a light-emitting device according to an embodiment of the present technology includes forming a plurality of light-emitting sources on a substrate.

The substrate is partitioned into a plurality of regions such that each of the plurality of regions includes a specified number of light-emitting sources from among the plurality of light-emitting sources.

A plurality of through-holes is formed at a boundary of adjacent regions of the plurality of regions.

Cutting is performed along the boundary of the adjacent regions of the plurality of regions such that the plurality of through-holes is divided.

A method for producing a light-emitting device according to another embodiment of the present technology includes forming a plurality of light-emitting sources on a substrate.

The substrate is partitioned into a plurality of regions such that each of the plurality of regions includes a specified number of light-emitting sources from among the plurality of light-emitting sources.

Cutting is performed along a boundary of adjacent regions of the plurality of regions.

A concave portion and a convex portion are formed in a cutting plane obtained by the cutting, the concave portion and the convex portion being alternately arranged in a specified direction.

### Advantageous Effects of Invention

As described above, the present technology makes it possible to control light emitted from a side surface. Note that the effect described here is not necessarily limitative, and any of the effects described in the present disclosure may be provided.

### BRIEF DESCRIPTION OF DRAWINGS

FIG. 1 schematically illustrates an appearance of an LED device according to an embodiment.

FIG. 2 is an enlarged schematic view illustrating a concavo-convex structure formed on a side surface.

FIG. 3 is a schematic diagram for describing a distribution of an emission direction of emission light emitted from the side surface.

FIG. 4 schematically illustrates side surfaces of comparative examples.

FIG. 5 schematically illustrates an appearance of an LED array.

FIG. 6 is a diagram for describing an effect provided by the concavo-convex structure.

FIG. 7 is a diagram for describing the effect provided by the concavo-convex structure.

FIG. 8 is a schematic diagram for describing a method for producing the LED device (the LED array).

FIG. 9 schematically illustrates another example of a configuration of the concavo-convex structure.

FIG. 10 schematically illustrates another example of a configuration of the concavo-convex structure.

FIG. 11 is a diagram for describing a concavo-convex structure according to another embodiment.

FIG. 12 schematically illustrates an example of a configuration of a light-emitting device according to another embodiment.

FIG. 13 schematically illustrates an example of a configuration of a light-emitting device according to another embodiment.

### MODE(S) FOR CARRYING OUT THE INVENTION

Embodiments according to the present technology will now be described below with reference to the drawings.

### LED Array

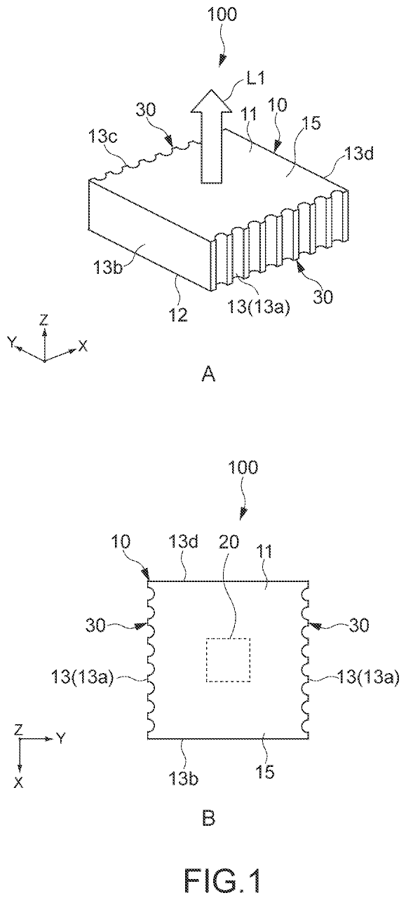

FIG. 1 schematically illustrates an appearance of an LED device according to an embodiment of the present technology. A of FIG. 1 is a perspective view of the LED device 100 as viewed from an oblique direction. B of FIG. 1 is a front view of the LED device 100 as viewed from the front. The LED device 100 corresponds to a light-emitting device in the present embodiment.

The LED device 100 includes a base 10 and an LED light-emitting source 20. The base 10 has a rectangular-parallelepiped shape as a whole, and includes a primary surface 11, a bottom surface 12, and four side surfaces 13 (13a to 13d). The primary surface 11, the bottom surface 12, and the four side surfaces 13 each have a rectangular outer shape.

For convenience of description, XYZ coordinate axes are set such that a plane direction of the primary surface 11 is an XY-plane direction and a perpendicular direction of the primary surface 11 is a Z-direction.

The side of the primary surface 11 of the base 10 is a front side of the LED device 100, and the side of the bottom surface 12 is a back side of the LED device 100. When the LED device 100 is used, it is possible to set any direction to be a front direction (corresponding to the perpendicular direction of the primary surface 11) that is a direction in which the primary surface 11 is oriented.

In the present embodiment, the entirety of the primary surface 11 is a light extraction surface 15. Thus, the plane direction and the perpendicular direction of the primary surface 11 respectively correspond to a plane direction and a perpendicular direction of the light extraction surface 15. As illustrated in A of FIG. 1, exit light L1 exits in the front direction from the light extraction surface 15. In other words, the exit light L1 exits in a direction parallel to the perpendicular direction of the light extraction surface 15.

Note that, when the primary surface 11 is formed of a light-blocking material, a transparent (light-transmissive) light extraction portion may be formed in a portion paired with the LED light-emitting source 20. In this case, a region that is a portion of the light extraction surface 15 is configured as the light extraction portion.

Note that the light extraction surface 15 is not limited to being formed in the same plane as the primary surface 11. The light extraction surface 15 may slightly protrude or be slightly recessed with respect to the primary surface 11.

The side surface 13 is a surface orthogonal to the primary surface 11 (the light extraction surface 15). The side surfaces 13b and 13d extend in a Y-direction, and face each other in an X-direction. The side surfaces 13a and 13c extend in the X-direction, and face each other in the Y-direction.

In the present embodiment, the side surfaces 13a and 13c are cutting planes when a wafer is cut into pieces to obtain the LED device 100. In other words, the side surfaces 13a and 13cmay also be referred to as end surfaces of the LED device 100.

In the present embodiment, a concavo-convex structure 30 is formed on each of the side surfaces 13a and 13c. Of course, the surface on which the concavo-convex structure 30 is formed is not limited, and, for example, the concavo-convex structure 30 may be formed on each of the side surfaces 13b and 13d. The concavo-convex structure 30 will be described in detail later.

The LED light-emitting source 20 is supported by the base 10. For example, the LED light-emitting source 20 may be situated on the side of the light extraction surface 15 (the side of a front surface) with respect to the primary surface 11, or may be situated on the side opposite to a light extraction direction (the side of a back surface). Further, the light extraction surface 15 may be the LED light-emitting source 20 itself. In the present embodiment, a semiconductor light-emitting section is implemented by a single LED light-emitting source 20.

A specific configuration for implementing the base 10 and the LED light-emitting source 20 is not limited. For example, it is possible to implement the base 10 and the LED light-emitting source 20 including a p-type semiconductor layer and an n-type semiconductor layer by growing, on a transparent (light-transmissive) growth substrate, an epitaxial layer made of a semiconductor material. Moreover, a p-electrode, an n-electrode, wiring, and the like are provided to the base 10.

For example, a growth substrate may be arranged on the side of the primary surface 11, and the LED light-emitting source 20 may be formed on the side of the bottom surface 12. Light emitted from the LED light-emitting source 20 is transmitted through the growth substrate from the side of the bottom surface 12, and exits from the light extraction surface 15. Alternatively, the growth substrate may be arranged on the side of the bottom surface 12, and the LED light-emitting source 20 may be formed on the side of the primary surface 11. Moreover, any configuration for implementing an LED device may be adopted.

The material of a growth substrate and a semiconductor material are also not limited, and any material may be used. For example, a substrate made of GaN, sapphire, GaAs, InP, Si, SiC, GaP, or ZnSe is used as the growth substrate. Of course, the material of the growth substrate is not limited to these materials.

Further, a GaInN-based semiconductor material is used as a semiconductor material, and the exit light L1 of a wavelength band from ultraviolet light to visible light may exit. Alternatively, a GaP-based, AlGaAs-based, or InP-based semiconductive material may be used, and the exit light L1 of a wavelength band from visible light to infrared light may exit. Moreover, any semiconductor material may be used. Further, a transparent insulator may be used with respect to an emission wavelength using, for example, a bonding technique. Examples of such an insulator include SiO2 (quartz), Al2O3 (sapphire), and other glasses. The present technology is applicable without the wavelength band of the exit light L1 being limited.

In the present embodiment, the entirety of the base 10 is transparent to light from the LED light-emitting source 20 that has an emission wavelength. The light emitted from the LED light-emitting source 20 also propagates in a direction different from the direction toward the light extraction surface 15. Of course, the present technology is also applicable when only a portion of the base 10 has transparency.

### Concavo-Convex Structure

The inventors have discussed an influence of light that propagates through the base 10 from the LED light-emitting source 20 and is emitted from the side surface 13. Then, the concavo-convex structure 30 used to control an emission direction of light emitted from the side surface 13 has been newly devised. The concavo-convex structure 30 described below can also be referred to as a structure for controlling a light emission direction, or a leaked-light control structure. Further, focused on the shape of the concavo-convex structure 30, the concavo-convex structure 30 can also be referred to as a corrugated structure or a structure having a corrugated shape.

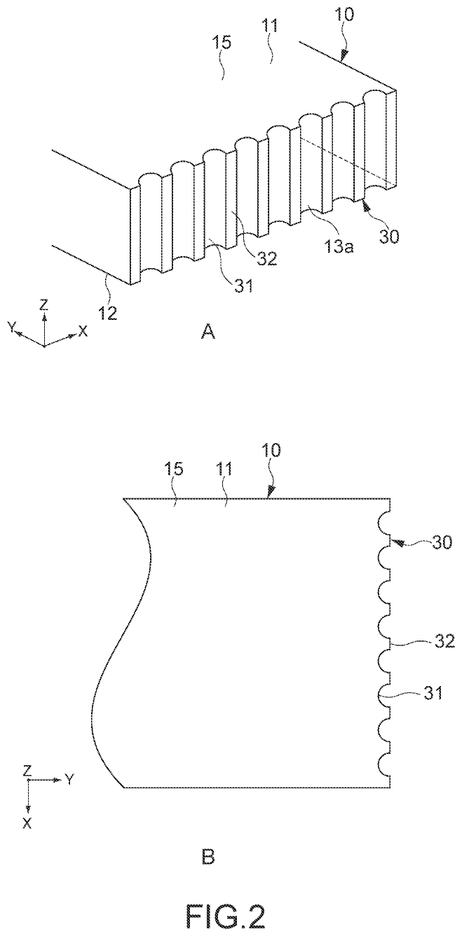

FIG. 2 is an enlarged schematic view illustrating the concavo-convex structure 30 formed on the side surface 13a. A of FIG. 2 is a perspective view of the concavo-convex structure 30 as viewed from an oblique direction. B of FIG. 2 illustrates the concavo-convex structure 30 as viewed from the front direction (the Z-direction).

As illustrated in FIG. 2, a concave portion 31 and a convex portion 32 that are alternately arranged in a specified direction are formed as the concavo-convex structure 30. In the present embodiment, a plurality of concave portions 31 and a plurality of convex portions 32 are formed such that the concave portion 31 and the convex portion 32 are alternately arranged in the X-direction orthogonal to an exit direction (the Z-direction) of the exit light L1 exiting from the light extraction surface 15.

In other words, the plurality of concave portions 31 and the plurality of convex portions 32 are formed in the X-direction such that the concave portion 31 and the convex portion 32 are alternately arranged one by one. This also corresponds to the fact that the plurality of concave portions 31 and the plurality of convex portions 32 are formed such that the concave portion 31 and the convex portion 32 are alternately arranged in a direction orthogonal to the perpendicular direction of the light extraction surface 15. As described above, in the present embodiment, the X-direction corresponds to a specified direction, and the Z-direction corresponds to a direction orthogonal to the specified direction.

In the present embodiment, the semicircular concave portion 31 is formed to extend in the Z-direction, as illustrated in A of FIG. 2. Eight semicircular concave portions 31 are formed to be equally spaced in the X-direction. A portion situated between adjacent semicircular concave portions 31 from among the eight semicircular concave portions 31 is the convex portion 32. Thus, the plurality of convex portions 32 is also formed to extend in the Z-direction.

Thus, when the plurality of concave portions 31 and the plurality of convex portions 32 are viewed from the Z-direction, the concave portions 31 of the plurality of concave portions 31 have the same shape, and are each formed to have a semicircular shape, as illustrated in B of FIG. 2. Further, except for portions at both ends, the concave portions 31 of the plurality of concave portions 31 have the same shape, and are each formed to have a mountain shape having a planar top.

In other words, in the present embodiment, the concavo-convex structure 30 is formed such that a circular arc and a planar surface are alternately arranged. Note that it is possible to cause all of the convex portions 32 of the plurality of convex portions 32 to have the same shape by forming the plurality of concave portions 31 such that the concave portions 31 are in contact with the two ends of the side surface 13a.

Note that a portion forming the concave portion 31 and a portion forming the convex portion 32 do not necessarily have to be clearly distinguished from each other. For example, a curved surface forming a semicircular shape can also be considered a portion of the concave portion 31 or a portion of the convex portion 32.

The following is an example of a method for defining the shapes of the concave portion 31 and the convex portion 32. Virtual lines respectively passing through a most protruding point and a most recessed point when the concavo-convex structure 30 is viewed from the Z-direction, are drawn in the X-direction. Then, it is possible to define the shapes of the concave portion 31 and the convex portion 32 using the two virtual lines as references. Of course, the method is not limited to such a method.

Note that the concave portion 31 and the convex portion 32 are not limited to being formed over an entire region of the side surface 13a in the Z-direction. A plurality of concave portions 31 and a plurality of convex portions 32 may be formed only in a central region, in the side surface 13a, that is situated from a position slightly further inward from the side of the primary surface 11 to a position slightly further inward from the side of the bottom surface 12. In this case, the effect of controlling an emission direction of emission light is also provided.

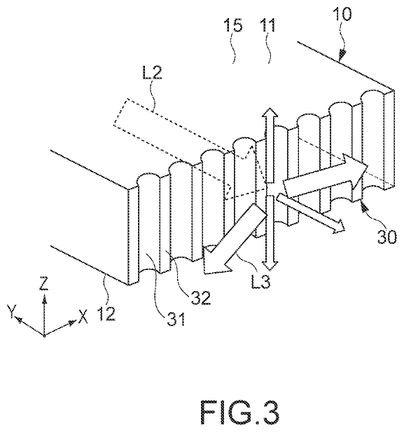

FIG. 3 is a schematic diagram for describing a distribution of an emission direction of emission light emitted from the side surface 13a. For example, light L2 emitted from the LED light-emitting source 20 propagates through the base 10 and reaches the side surface 13a (the light L2 may be hereinafter referred to as propagation light L2). In FIG. 3, the propagation light L2 is indicated by a dashed arrow that extends in a certain direction. However, the propagation light L2 enters the side surface 13a from various directions (at various angles).

The propagation light L2 entering the side surface 13a travels in accordance with Snell's law. In other words, when an angle of incidence of light on the side surface 13a is smaller than a critical angle, the light is emitted to the outside from the side surface 13a in a direction corresponding to a direction of incidence (an angle of incidence) on the side surface 13a. On the other hand, when the angle of incidence of the light on the side surface 13a is smaller than the critical angle, the light is not emitted from the side surface 13a and travels through the base 10.

In the present embodiment, a plurality of concave portions 31 and a plurality of convex portions 32 are formed in the X-direction. Thus, it is possible to guide an emission direction of emission light L3 emitted from the side surface 13a in the XY-plane direction. In other words, it is possible to concentrate a light distribution performance of the emission light L3 emitted from the side surface 13a in the XY-plane direction. This results in being able to suppress the emission light L3 emitted in the exit direction (the front direction) of the exit light L1 exiting from the light extraction surface 15.

Note that, with respect to light intensity of the emission light L3 guided to the XY-plane, the distribution of the light intensity in the XY-plane is not limited. For example, there is a possibility that, in the XY-plane, the light intensity of the emission light L3 traveling in a direction of a specified angle relative to the side surface 13a will be relatively high, and the light intensity of the emission light L3 traveling in a direction of an angle other than the specified angle will be relatively low. The distribution of the light intensity of the emission light L3 in the XY-plane varies depending on, for example, the shape of the concavo-convex structure 30.

In any case, scattering of the emission light L3 from the side surface 13a can be guided to the XY-plane. Thus, the amount of the emission light L3 emitted in the front direction is sufficiently suppressed. Note that the amount of the emission light L3 emitted to the back side is also suppressed.

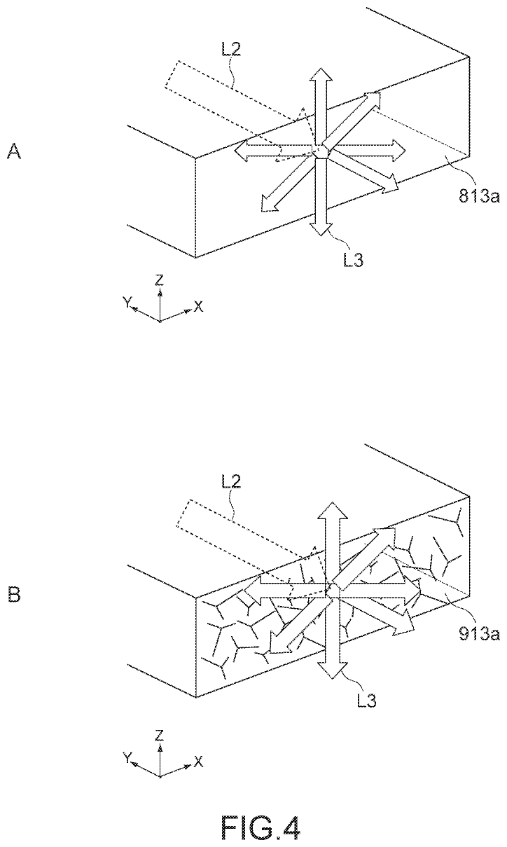

FIG. 4 schematically illustrates side surfaces of comparative examples. In the example illustrated in A of FIG. 4, a side surface 813a is formed of a smooth surface. In this case, when the propagation light L2 reaches the side surface 813a, the emission light L3 is uniformly scattered in all directions.

In the example illustrated in B of FIG. 4, a side surface 913a is formed of a randomly concavo-convex surface. For example, an LED array is obtained by performing cutting into pieces using, for example, a blade dicer, or cleavage is performed by a wafer being pressed against a blade. In such cases, an end surface obtained by the cutting is a randomly concavo-convex surface such as the side surface 913a. When the side surface 913a is a randomly concavo-convex surface, the light intensity of the emission light L3 is increased in all directions.

Here, an effect provided by the concavo-convex structure 30 according to the present technology is described. For this purpose, an LED array that is another embodiment of the light-emitting device according to the present technology is described first.

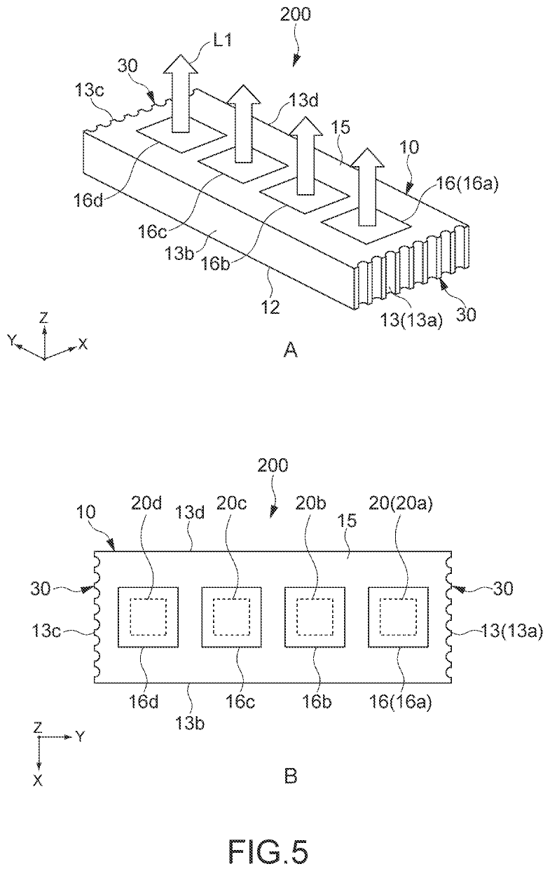

FIG. 5 schematically illustrates an appearance of an LED array 200. A of FIG. 5 is a perspective view of the LED array 200 as viewed from an oblique direction. B of FIG. 5 is a front view of the LED array 200 as viewed from the front.

The LED array 200 is provided with four LED light-emitting sources 20 (20a to 20d). Further, four light extraction portions 16 (16a to 16d) are provided on the light extraction surface 15 correspondingly to the four LED light-emitting sources 20. The concavo-convex structure 30 is formed on each of the side surfaces 13a and 13c that face each other in the Y-direction.

In the LED array 200 illustrated in FIG. 5, a semiconductor light emitting portion is implemented by the four LED light-emitting sources 20. As described above, the present technology is also applicable when the semiconductor light-emitting section includes a plurality of LED light-emitting sources 20. In other words, the present technology is applicable to a semiconductor light-emitting device that includes any number of LED light-emitting sources 20 not less than one.

In the present embodiment, the following method is assumed to be a method for using the LED array 200 illustrated in FIG. 5. In other words, a plurality of LED arrays 200 is arranged in the Y-direction in which the light extraction portions 16 are arranged. Then, a lighting operation performed by the LED light-emitting source 20 included in each LED array 200 is controlled as appropriate.

For example, the LED light-emitting sources 20 are turned on independently of each other, and the exit light L1 exits from each LED light-emitting source 20. Alternatively, any number of LED light-emitting sources 20 not less than two are simultaneously turned on, and a plurality of pieces of exit light L1 exits simultaneously. It is possible to output an optical signal by performing such a lighting control and causing the exit light L1 to exit. For example, such output of an optical signal that is performed using the LED array 200 is applicable to an apparatus such as an LED printer.

If light is emitted in the front direction of the light extraction surface 15 from the side surfaces 13a and 13c that face each other in the Y-direction, the emission light may be received as an erroneous signal when the LED array 200 is used to output an optical signal. Thus, in the present embodiment, the concavo-convex structure 30 is formed on each of the side surfaces 13a and 13c. Of course, the surface on which the concavo-convex structure 30 is formed is not limited, and, for example, the concavo-convex structure 30 may be formed on each of the side surfaces 13b and 13d.

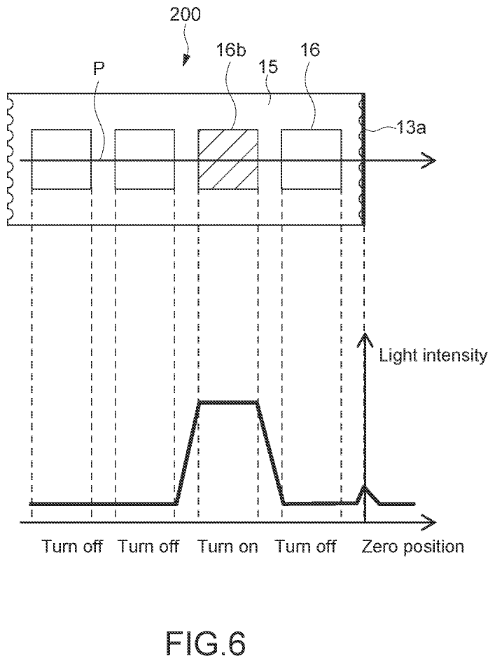

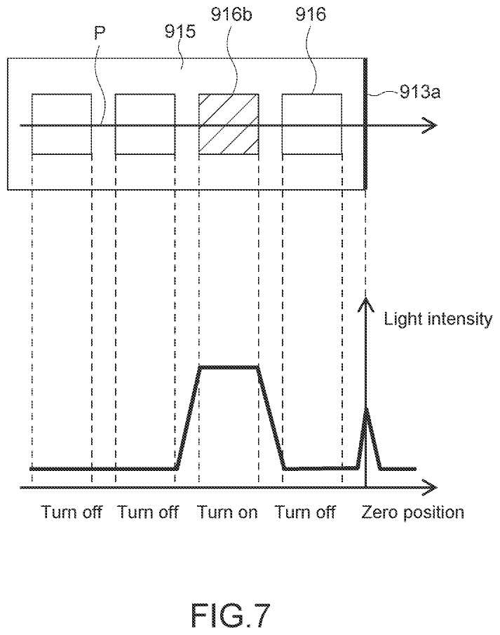

FIGS. 6 and 7 are diagrams for describing an effect provided by the concavo-convex structure 30. FIG. 6 schematically illustrates a light emission profile with respect to the LED array 200 illustrated in FIG. 5. FIG. 7 schematically illustrates a light emission profile with respect to an LED array that includes the side surface 913a illustrated in B of FIG. 4.

As illustrated in FIGS. 6 and 7, the side surfaces 13a and 913a that are situated on the right in the respective figures are each set to be a zero position, and LED light-emitting sources (of which illustrations are omitted) that respectively correspond to the light extraction portion 16b and a light extraction portion 916b are turned on, the light extraction portions 16b and 916b being the respective second light extraction portions as viewed from the side surfaces 13a and 913a. The other LED light-emitting sources are turned off. Then, the light intensity is measured from the front side, with center positions of the light extraction surface 15 and a light extraction surface 915 (the LED light-emitting sources) each being a profile measurement position P.

As illustrated in FIGS. 6 and 7, compared with the side surface 913a that is a randomly concavo-convex surface, the light intensity of the emission light L3 leaked in the exit direction of the exit light L1 is suppressed on the side surface 13a on which the concavo-convex structure 30 according to the present technology is formed. This makes it possible to sufficiently suppress the signal intensity due to the side surface 13a, and to sufficiently suppress the occurrence of an erroneous signal.

### Method for Producing LED Array

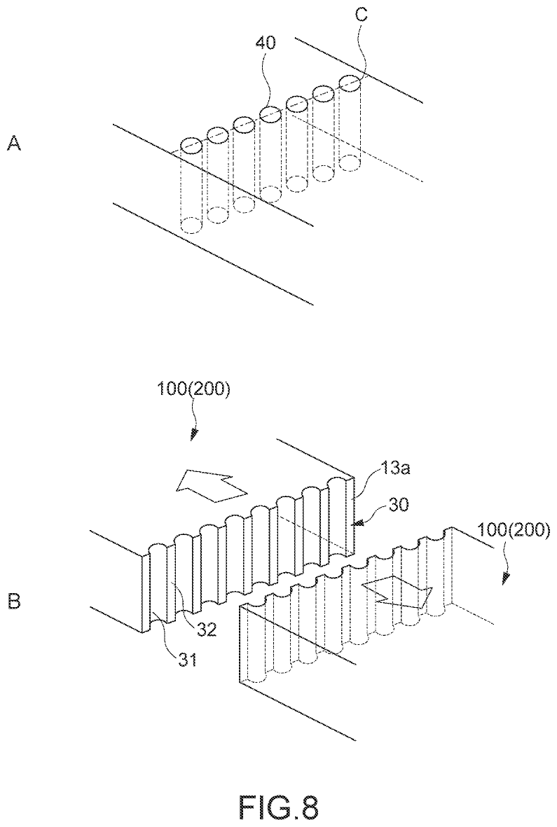

FIG. 8 is a schematic diagram for describing a method for producing the LED device 100 (the LED array 200). As described in detail below, a cutting method used in the present technology is a commonly used general-purpose method, and there is no need for an additional special area in order to practice the present technology. Thus, it is possible to control a direction of light emitted from the side surface 13 while maintaining the productivity (the number of products that can be secured per production unit).

A plurality of LED light-emitting sources 20 is collectively formed on a wafer (a substrate), and an electrode, wiring, and the like are also formed. The wafer is partitioned into a plurality of regions such that each of the plurality of regions includes a specified number of LED light-emitting sources 20.

When the LED device 100 illustrated in FIG. 1 is produced, a wafer is partitioned into a plurality of regions such that each of the plurality of regions includes a single LED light-emitting source 20. When the LED array 200 illustrated in FIG. 5 is produced, a wafer is partitioned into a plurality of regions such that each of the plurality of regions include four LED light-emitting sources 20.

As illustrated in A of FIG. 8, a plurality of through-holes 40 is formed at a boundary of adjacent regions of the plurality of regions obtained by the partitioning (a cutting line C). For example, a plurality of openings is patterned in the boundary line C by a photolithography process. Then, the plurality of through-holes 40 is formed by, for example, dry etching, wet etching, or electrochemical etching. Alternatively, an etching technique such as electrochemical anisotropic etching or light irradiation may be used without patterning. Moreover, any technique may be used to form the through-hole 40.

Cutting is performed along the cutting line C corresponding to the boundary of the adjacent regions of the plurality of regions, such that the plurality of through-holes 40 is divided. For example, cleavage is performed by pressing a blade to the cutting line C. Accordingly, the LED device 100 (the LED array 200) including a specified number of LED light-emitting sources 20 is formed. The concavo-convex structure 30 including a plurality of concave portions 31 and a plurality of convex portions 32 is formed on each of the side surfaces 13a and 13c that are end surfaces, the concave portion 31 and the convex portion 32 being alternately arranged in a certain direction.

A through-hole is formed, and the LED device 100 (the LED array 200) is obtained by performing cutting into pieces on the basis of the formed through-hole, as described above. This makes it possible to easily produce, without adding a special process, the LED device 100 (the LED array 200) including the concavo-convex structure 30 formed on the side surface 13.

Note that a plurality of through-holes 40 is formed such that the through-holes 40 of the plurality of through-holes 40 overlap without being spaced. This also makes it possible to obtain the LED device 100 (the LED array 200) by directly performing cutting into pieces in the process of forming the plurality of through-holes 40. This results in being able to reduce the number of production processes. Note that the shape of the concavo-convex structure 30 corresponds to a state of an overlap of the through-holes 40. Of course, it is also possible to sufficiently control the emission direction of the emission light L3 in this case.

In other words, a photolithography process, an etching process, and a cutting process (a process of applying pressure) make it possible to obtain the LED device 100 (the LED array 200) according to the present technology by performing cutting into pieces. Further, the photolithography process and the etching process also make it possible to obtain the LED device 100 (the LED array 200) by performing cutting into pieces.

The LED device 100 (the LED array 200) may be obtained by performing cutting into pieces, and then the concavo-convex structure 30 may be formed on an end surface of the obtained LED device 100 (the obtained LED array 200). This is another method for producing the LED device 100 (the LED array 200).

For example, cutting is performed along the cutting line C without forming the through-hole 40 illustrated in A of FIG. 8. It is possible to produce the LED device 100 (the LED array 200) including the concavo-convex structure 30 formed on each of the side surfaces 13a and 13c, by forming a plurality of concave portions 31 and a plurality of convex portions 32 in a cutting plane obtained by the cutting, the concave portion 31 and the convex portion 32 being alternately arranged in a specified direction. In this case, any technique such as performing cutting using a blade dicer, or performing cleavage by pressing a blade and by applying pressure, may be used for performing cutting into pieces. It is also possible to form an alteration layer on a wafer using a laser and then to perform cutting into pieces.

### Other Examples of Concavo-Convex Structure

In the concavo-convex structure 30 illustrated in FIG. 2, the semicircular concave portion 31 is formed, as viewed from the Z-direction. The shape of the concave portion 31 is not limited to a semicircular shape, and any circular-arc-shaped concave portion may be formed. Note that, in the present disclosure, the circular arc is not limited to a shape of a true circular arc, and includes an arc shape such as an ellipse. Moreover, a concave portion having any curved shape, as viewed from the X-direction, may be formed.

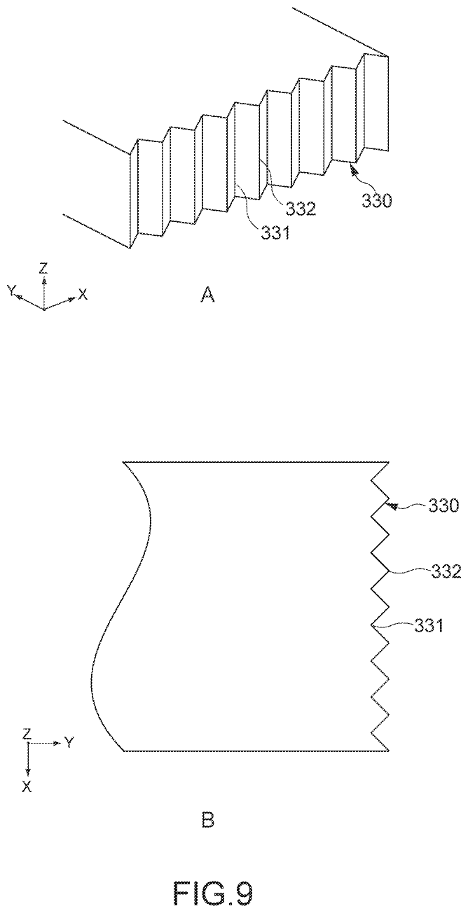

As illustrated in FIG. 9, a V-shaped concave portion 331, as viewed from the Z-direction, may be formed. In the example illustrated in FIG. 9, a plurality of V-shaped concave portions 331 and a plurality of V-shaped convex portions 332 are formed such that the concave portion 331 and the convex portion 332 are alternately arranged in the X-direction. In other words, a concavo-convex structure 330 may be formed of an angled planar surface. Note that the angle and the like of the V-shape are not limited, and may be designed discretionarily.

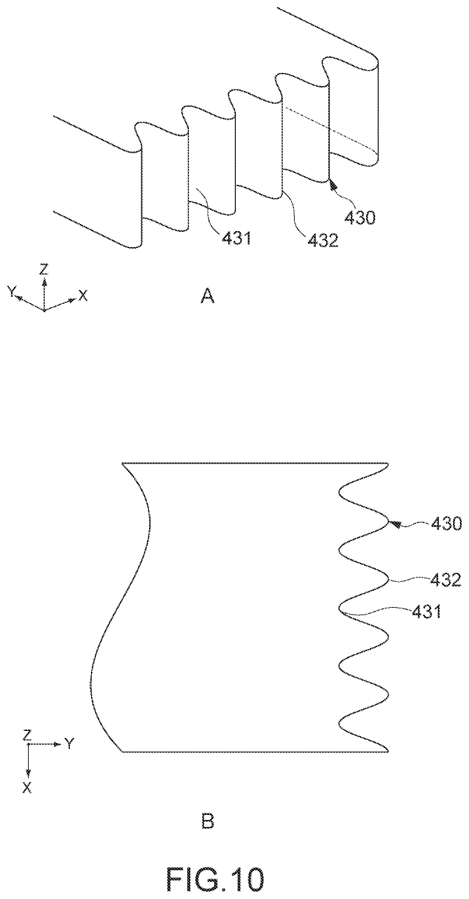

As illustrated in FIG. 10, the sinusoidal shape may be formed by a plurality of concave portions 431 and a plurality of convex portions 432, as viewed from the Z-direction. In other words, a concavo-convex structure 430 may be formed to be sinusoidal in shape. The magnitude of amplitude, the cycle, and the like are not limited, and may be designed discretionarily.

A result of measuring a light emission profile shows that the semicircular concavo-convex structure 30 illustrated in FIG. 2 provides a relatively greater effect of suppressing the intensity of an erroneous signal than the V-shaped concavo-convex structure 330 illustrated in FIG. 9. The result further shows that the concavo-convex structure 430 sinusoidal in shape illustrated in FIG. 10 provides a relatively greater effect of suppressing the intensity of an erroneous signal than the semicircular concavo-convex structure 30 illustrated in FIG. 2. Of course, those are relative comparison results obtained by comparing two concavo-convex structures, and they do not mean that the V-shaped concavo-convex structure 330 provides a small effect.

Moreover, the result also shows that a great suppression effect is provided by arranging a concave portion and a convex portion at high densities, and a small suppression effect is provided by arranging a concave portion and a convex portion at low densities. In any case, the shape of the concavo-convex structure is not limited, and any shape that makes it possible to guide the emission light L3 in a direction in which the concave portion and the convex portion are arranged may be adopted.

As described above, in the LED device 100 (the LED array 200) according to the present embodiment, the concave portion 31 and the convex portion 32 that are arranged in a specified direction are formed on the side surface 13 of the base 10 including the light extraction surface 15. This makes it possible to control the emission direction (a scattering direction) of the emission light L3 emitted from the side surface 13. This results in being able to sufficiently suppress the occurrence of an erroneous signal.

Further, the concavo-convex structure 30 is obtained by forming a plurality of concave portions 31 using, as a reference position, the position of the end surface corresponding to the side surface 13 (the position of the cutting line C). In this case, a portion that protrudes from the side surface 13 beyond the reference position is not formed. Thus, it is possible to closely arrange a plurality of LED devices 100 (a plurality of LED arrays 200) to be brought into contact with each other at the reference position. Consequently, the respective LED light-emitting sources 20 of adjacent LED devices 100 (adjacent LED arrays 200) can be equally spaced without being displaced.

Furthermore, it is assumed that, for example, a phosphor that emits specified colored light is formed on the primary surface 11 using the exit light L1 as excitation light. In this case, if leaked light exits from the side surface 13 in the front direction, color unevenness may be caused in the colored light emitted from the phosphor. The adoption of the concavo-convex structure 30 according to the present technology also makes it possible to prevent such a problem with color unevenness.

Moreover, it is assumed that a phosphor that emits specified colored light is formed on each of the primary surface 11 and the side surface 13. Since the thickness of the phosphor differs depending on the angle at which a light source of the phosphor is observed, the thickness of the phosphor may cause color unevenness after color conversion is performed. It is also possible to prevent such a problem with color unevenness from occurring due to an observation angle, by adopting the concavo-convex structure 30 according to the present technology to perform adjustment such that the ratio of the exit light L1 to the thickness of a phosphor of the primary surface 11 and the ratio of the emission light L3 to the thickness of the phosphor of the side surface 13 are the same.

<Other Embodiments>

The present technology is not limited to the embodiments described above, and can achieve various other embodiments.

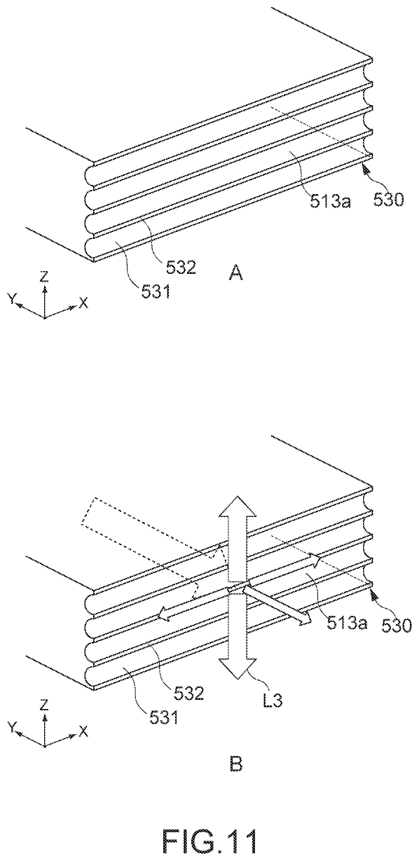

FIG. 11 is a diagram for describing a concavo-convex structure according to another embodiment. A of FIG. 11 schematically illustrates an example of a configuration of a concavo-convex structure 530 formed on a side surface 513a. B of FIG. 11 is a schematic diagram for describing a distribution of the emission direction of the emission light L3 emitted from the side surface 513a.

In the example illustrated in FIG. 11, a plurality of concave portions 531 and a plurality of convex portions 532 are formed as the concavo-convex structure 530 such that the concave portion 531 and the convex portion 532 are alternately arranged in the Z-direction parallel to the exit direction (the Z-direction) of the exit light L1 exiting from a light extraction surface. In other words, the plurality of concave portions 531 and the plurality of convex portions 532 are formed such that the concave portion 531 and the convex portion 532 are alternately arranged in a direction parallel to a perpendicular direction of a primary surface.

In the example illustrated in FIG. 11, the Z-direction corresponds to a specified direction, and the X-direction corresponds to a direction orthogonal to the specified direction. The plurality of concave portions 531 and the plurality of convex portions 532 are formed to extend in the Z-direction. The shape of the plurality of concave portions 531 and the plurality of convex portions 532 as viewed from the Z-direction is not limited, and may be designed discretionarily, such as a circular-arc shape, a V-shape, or a sinusoidal shape.

As illustrated in B of FIG. 11, the emission direction of the emission light L3 emitted from the side surface 513a is guided in the XY-plane direction. A light distribution performance of the emission light L3 emitted from the side surface 513a is concentrated in the XY-plane direction. This results in being able to further increase the intensity of light in the exit direction (the front direction) of the exit light L1 exiting from the light extraction surface. In other words, it is possible to increase the light intensity in the front direction.

For example, when an LED array is used as a light source apparatus of an image display apparatus, or a lighting apparatus, it is necessary that the light efficiency and the brightness be improved. It is possible to improve the light efficiency and the brightness by forming the concavo-convex structure 530 as illustrated in FIG. 11.

As described above, it is possible to control, as appropriate, a direction in which a light distribution performance is to be improved by controlling, as appropriate, a direction in which a convex portion and a concave portion are arranged. For example, a concavo-convex structure may be formed in a direction oblique to the exit direction of the exit light L1.

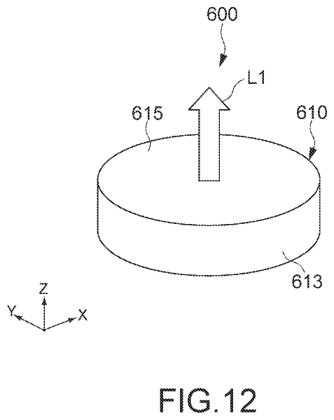

FIG. 12 schematically illustrates an example of a configuration of a light-emitting device according to another embodiment. In a light-emitting device 600 illustrated in FIG. 12, a base 610 has a cylindrical shape of which an axis direction is a perpendicular direction of a light extraction surface 615 (the Z-direction). Further, a concavo-convex structure (of which an illustration is omitted) having any configuration is formed on a side surface 613 of the base 610. Furthermore, an outer shape of the base is not limited, and any shape may be adopted.

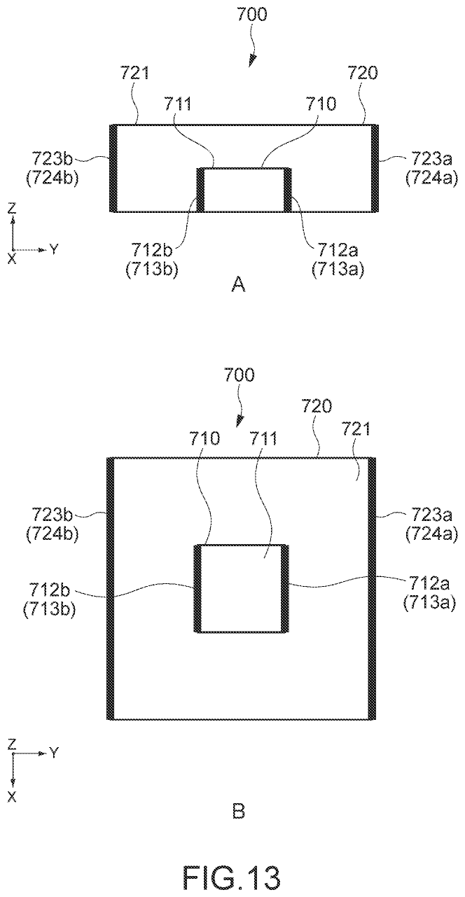

FIG. 13 schematically illustrates an example of a configuration of a light-emitting device according to another embodiment. In the example illustrated in FIG. 13, an LED package 700 is formed as a light-emitting device. The LED package 700 includes an LED device 710 and a transparent (light-transmissive) cover portion 720. A packaged light-emitting device is obtained by covering the LED device 710 with the cover portion 720.

The LED device 710 includes a light extraction surface 711 from which exit light exits, and side surfaces 712a and 712b that face each other in the Y-direction. Concavo-convex structures 713a and 713b according to the present technology are respectively formed on the side surfaces 712a and 712b. In the present embodiment, a concave portion and a convex portion (of which illustrations are omitted) that are alternately arranged in the X-direction are formed as each of the concavo-concave portion structures 713a and 713b. The LED device 710 itself is also included in one of the embodiments of the light-emitting device according to the present technology. A specific configuration of the LED device 710 is not limited, and the LED device 710 may be designed discretionarily.

The cover portion 720 is configured to cover the light extraction surface 711 and the side surfaces 712a and 712b of the LED device 710. In the example illustrated in FIG. 13, a portion other than a bottom surface of the LED device 710 is covered with the cover portion 720. The material of the cover portion 720 is not limited, and the cover portion 720 is made of, for example, glass or a resin material.

The cover portion 720 includes a primary surface 721 that faces the light extraction surface 711 of the LED device 710. Light exiting from the light extraction surface 711 of the LED device 710 exits from the primary surface 721 of the cover portion 720.

Further, the cover portion 720 includes side surfaces 723a and 723b that face each other in the Y-direction. Concavo-convex structures 724a and 724b according to the present technology are respectively formed on the side surfaces 723a and 723b. In the present embodiment, a concave portion and a convex portion (of which illustrations are omitted) that are alternately arranged in the X-direction are formed as each of the concavo-concave portion structures 724a and 724b.

It is also possible to respectively apply the concavo-convex structures 724a and 724b according to the present technology to the side surfaces 723a and 723b of the cover portion 720 used to perform packaging as described above. This makes it possible to control an emission direction of emission light emitted from the side surfaces 723a and 723b of the cover portion 720, and to similarly exert the effect described above.

The LED device (the LED array) has been described above as an example of the light-emitting device. Without being limited thereto, the present technology is also applicable to other light-emitting devices such as a laser diode (LD) device. In other words, the present technology is applicable to a semiconductor light-emitting section that includes a light-emitting source different from an LED light-emitting source.

The LED device, the LED array, the concavo-convex structure, the LED package, the production processes, and the like described with reference to the respective figures are merely embodiments, and any modifications may be made thereto without departing from the spirit of the present technology. In other words, for example, any other configurations and any production processes for purpose of practicing the present technology may be adopted.

In the present disclosure, expressions such as “rectangular shape”, “rectangular-parallelepiped shape”, “cylindrical shape”, “orthogonal”, “parallel”, “the same”, “central portion”, “semicircular/semicircular shape”, “V-shaped”, and “sinusoidal shape/sinusoidal in shape” respectively include, in concept, expressions such as “substantially rectangular shape”, “generally-rectangular-parallelepiped shape”, “substantially cylindrical shape”, “substantially orthogonal”, “substantially parallel”, “substantially the same”, “substantially central portion”, “substantially semicircular/substantially semicircular shape”, “generally V-shaped”, and “substantially sinusoidal shape/substantially sinusoidal in shape”. For example, the expressions such as “rectangular shape”, “rectangular-parallelepiped shape”, “cylindrical shape”, “orthogonal”, “parallel”, “the same”, “central portion”, “semicircular/semicircular shape”, “V-shaped”, and “sinusoidal shape/sinusoidal in shape” also respectively include states within specified ranges (such as a range of +/−10%), with expressions such as “perfectly rectangular shape”, “perfectly rectangular-parallelepiped shape”, “perfectly cylindrical shape”, “perfectly orthogonal”, “perfectly parallel”, “exactly the same”, “exactly central portion”, “perfectly semicircular/perfectly semicircular shape”, “fully V-shaped”, and “perfectly sinusoidal shape/perfectly sinusoidal in shape” being respectively used as references. It is also possible to use other wording such as “approximately rectangular shape”.

At least two of the features of the present technology described above can also be combined. In other words, various features described in the respective embodiments may be combined discretionarily regardless of the embodiments. Further, the various effects described above are not limitative but are merely illustrative, and other effects may be provided.

(1) A light-emitting device, including:

a semiconductor light-emitting section; and

a base that supports the semiconductor light-emitting section, and includes a light extraction surface and a side surface including a concave portion and a convex portion that are alternately arranged in a specified direction.

(2) The light-emitting device according to (1), in which

the side surface includes a plurality of the concave portions and a plurality of the convex portions, and

the concave portion and the convex portion are alternately arranged one by one in the specified direction.

(3) The light-emitting device according to (2), in which

the concave portion and the convex portion are alternately arranged in a direction orthogonal to an exit direction of light that exits from the light extraction surface.

(4) The light-emitting device according to (2) or (3), in which

the concave portion and the convex portion are alternately arranged in a direction orthogonal to a perpendicular direction of the light extraction surface.

(5) The light-emitting device according to any one of (2) to (4), in which

the base has a rectangular-parallelepiped shape, and

the side surface is a surface orthogonal to the light extraction surface.

(6) The light-emitting device according to any one of (2) to (4), in which

the base has a cylindrical shape of which an axis direction is a perpendicular direction of the light extraction surface, and

the side surface is a circumferential surface of the base.

(7) The light-emitting device according to any one of (2) to (6), in which

the concave portion and the convex portion are configured to extend on the side surface in a direction orthogonal to the specified direction.

(8) The light-emitting device according to any one of (2) to (7), in which

the concave portions of the plurality of the concave portions have the same shape when the plurality of the concave portions and the plurality of the convex portions are viewed from a direction orthogonal to the specified direction.

(9) The light-emitting device according to any one of (2) to (8), in which

the convex portions of the plurality of the convex portions have the same shape when the plurality of the concave portions and the plurality of the convex portions are viewed from a direction orthogonal to the specified direction.

(10) The light-emitting device according to any one of (2) to (9), in which

each of the plurality of the concave portions has a shape of a circular arc when the plurality of the concave portions and the plurality of the convex portions are viewed from a direction orthogonal to the specified direction.

(11) The light-emitting device according to any one of (2) to (9), in which

each of the plurality of the concave portions has a semicircular shape when the plurality of the concave portions and the plurality of the convex portions are viewed from a direction orthogonal to the specified direction.

(12) The light-emitting device according to any one of (2) to (9), in which

each of the plurality of the concave portions has a V-shape when the plurality of the concave portions and the plurality of the convex portions are viewed from a direction orthogonal to the specified direction.

(13) The light-emitting device according to any one of (2) to (9), in which

a sinusoidal shape is formed by the plurality of the concave portions and the plurality of the convex portions when the plurality of the concave portions and the plurality of the convex portions are viewed from a direction orthogonal to the specified direction.

(14) The light-emitting device according to (2), in which

the concave portion and the convex portion are alternately arranged in a direction parallel to an exit direction of light that exits from the light extraction surface.

(15) The light-emitting device according to (2) or (14), in which

the concave portion and the convex portion are alternately arranged in a direction parallel to a perpendicular direction of the light extraction surface.

(16) The light-emitting device according to any one of (1) to (15), in which

the semiconductor light-emitting section includes at least one light-emitting source.

(17) The light-emitting device according to (16), in which

the at least one light-emitting source is at least one light-emitting diode (LED).

(18) The light-emitting device according to (16) or (17), in which

the at least one light-emitting source is arranged on a side of the light extraction surface of the base, or is arranged on a side opposite to the light extraction surface of the base.

(19) The light-emitting device according to any one of (1) to (18), further including

a cover portion that is configured to cover the light extraction surface and the side surface of the base, the cover portion including a side surface including a concave portion and a convex portion that are alternately arranged in a specified direction.

(20) A method for producing a light-emitting device, the method including:

forming a plurality of light-emitting sources on a substrate;

partitioning the substrate into a plurality of regions such that each of the plurality of regions includes a specified number of light-emitting sources from among the plurality of light-emitting sources;

forming a plurality of through-holes at a boundary of adjacent regions of the plurality of regions; and

performing cutting along the boundary of the adjacent regions of the plurality of regions such that the plurality of through-holes is divided.

(21) A method for producing a light-emitting device, the method including:

forming a plurality of light-emitting sources on a substrate;

partitioning the substrate into a plurality of regions such that each of the plurality of regions includes a specified number of light-emitting sources from among the plurality of light-emitting sources;

performing cutting along a boundary of adjacent regions of the plurality of regions; and

forming a concave portion and a convex portion in a cutting plane obtained by the cutting, the concave portion and the convex portion being alternately arranged in a specified direction.

### REFERENCE SIGNS LIST

L1 exit light

L2 propagation light

L3 emission light

10 base

11, 511 primary surface

13, 513, 613, 712 side surface of base

15 light extraction surface

20 LED light-emitting source

30, 330, 430, 530, 713, 72 concavo-convex structure

31, 331, 431, 531 concave portion

32, 332, 432, 532 convex portion

40 through-hole

100 LED device

200 LED array

700 LED package

710 LED device

720 cover portion

723 side surface of cover

1] A light-emitting device, comprising:
a semiconductor light-emitting section; and
a base that supports the semiconductor light-emitting section, and includes a light extraction surface and a side surface including a concave portion and a convex portion that are alternately arranged in a specified direction.

2] The light-emitting device according to claim 1, wherein
the side surface includes a plurality of the concave portions and a plurality of the convex portions, and
the concave portion and the convex portion are alternately arranged one by one in the specified direction.

3] The light-emitting device according to claim 2, wherein
the concave portion and the convex portion are alternately arranged in a direction orthogonal to an exit direction of light that exits from the light extraction surface.

4] The light-emitting device according to claim 2, wherein
the concave portion and the convex portion are alternately arranged in a direction orthogonal to a perpendicular direction of the light extraction surface.

5] The light-emitting device according to claim 2, wherein
the base has a rectangular-parallelepiped shape, and
the side surface is a surface orthogonal to the light extraction surface.

6] The light-emitting device according to claim 2, wherein
the base has a cylindrical shape of which an axis direction is a perpendicular direction of the light extraction surface, and
the side surface is a circumferential surface of the base.

7] The light-emitting device according to claim 2, wherein
the concave portion and the convex portion are configured to extend on the side surface in a direction orthogonal to the specified direction.

8] The light-emitting device according to claim 2, wherein
the concave portions of the plurality of the concave portions have the same shape when the plurality of the concave portions and the plurality of the convex portions are viewed from a direction orthogonal to the specified direction.

9] The light-emitting device according to claim 2, wherein
the convex portions of the plurality of the convex portions have the same shape when the plurality of the concave portions and the plurality of the convex portions are viewed from a direction orthogonal to the specified direction.

10] The light-emitting device according to claim 2, wherein
each of the plurality of the concave portions has a shape of a circular arc when the plurality of the concave portions and the plurality of the convex portions are viewed from a direction orthogonal to the specified direction.

11] The light-emitting device according to claim 2, wherein
each of the plurality of the concave portions has a semicircular shape when the plurality of the concave portions and the plurality of the convex portions are viewed from a direction orthogonal to the specified direction.

12] The light-emitting device according to claim 2, wherein
each of the plurality of the concave portions has a V-shape when the plurality of the concave portions and the plurality of the convex portions are viewed from a direction orthogonal to the specified direction.

13] The light-emitting device according to claim 2, wherein
a sinusoidal shape is formed by the plurality of the concave portions and the plurality of the convex portions when the plurality of the concave portions and the plurality of the convex portions are viewed from a direction orthogonal to the specified direction.

14] The light-emitting device according to claim 2, wherein
the concave portion and the convex portion are alternately arranged in a direction parallel to an exit direction of light that exits from the light extraction surface.

15] The light-emitting device according to claim 2, wherein
the concave portion and the convex portion are alternately arranged in a direction parallel to a perpendicular direction of the light extraction surface.

16] The light-emitting device according to claim 1, wherein
the semiconductor light-emitting section includes at least one light-emitting source.

17] The light-emitting device according to claim 16, wherein
the at least one light-emitting source is at least one light-emitting diode (LED).

18] The light-emitting device according to claim 16, wherein
the at least one light-emitting source is arranged on a side of the light extraction surface of the base, or is arranged on a side opposite to the light extraction surface of the base.

19] The light-emitting device according to claim 1, further comprising
a cover portion that is configured to cover the light extraction surface and the side surface of the base, the cover portion including a side surface including a concave portion and a convex portion that are alternately arranged in a specified direction.

20] A method for producing a light-emitting device, the method comprising:
forming a plurality of light-emitting sources on a substrate;
partitioning the substrate into a plurality of regions such that each of the plurality of regions includes a specified number of light-emitting sources from among the plurality of light-emitting sources;
forming a plurality of through-holes at a boundary of adjacent regions of the plurality of regions; and
performing cutting along the boundary of the adjacent regions of the plurality of regions such that the plurality of through-holes is divided.

21] A method for producing a light-emitting device, the method comprising:
forming a plurality of light-emitting sources on a substrate;
partitioning the substrate into a plurality of regions such that each of the plurality of regions includes a specified number of light-emitting sources from among the plurality of light-emitting sources;
performing cutting along a boundary of adjacent regions of the plurality of regions; and
forming a concave portion and a convex portion in a cutting plane obtained by the cutting, the concave portion and the convex portion being alternately arranged in a specified direction.
